(19) United States
(12) Patent Application Publication
(10) Pub. No.: US 2009/0160041 A1
(43) Pub. Date: Jun. 25, 2009

(54) Substrate package structure

(76) Inventor: Wen-Jeng Fan, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/071,611

(22) Filed: Feb. 25, 2008

(30) Foreign Application Priority Data
Dec. 21, 2007 (TW) 96149385

(51) Int. Cl. H01L 23/498

(52) U.S. Cl. 257/680; 257/E23.067; 257/E23.002

(57) ABSTRACT

A substrate package structure is disclosed herein. The substrate package structure includes a packaging substrate provided with a plurality of chip carriers set at one surface of the packaging substrate, wherein those chip carriers are formed by intersecting a plurality of cutting streets; a plurality of through holes set at those cutting streets and set around those chip carriers; and a plurality of molding areas set on another surface of the packaging substrate and opposite to those chip carriers, wherein those molding areas are adjacent to those through holes. Hence, those through holes may be flowed by the molding compound to form a plurality of molding bumps around those chip carriers so as to improve the crack problem of the chip and/or the substrate.

### BACKGROUND OF THE INVENTION

1. Field of the Invention

The present invention relates to a substrate package structure, and more particularly, to a substrate package structure for preventing the package from chip warpage at the edge.

2. Description of the Prior Art

IC packaging process is a back-end process in the semiconductor industry and includes following procedures: dicing, die attachment, wire bonding, encapsulation, printing, bumping, and singulation. The function of IC packaging is to provide an interface to transmit the internal IC signals to the external systems and enhance the strength of the IC chip and protect the IC chip from the corrosion and damage caused by water, moisture, chemical materials and external force.

In the molding process, a mold is placed on a substrate having semiconductor chips or electronic elements, and an encapsulant is filled into the cavity of the mold, and then the mold is stripped away.

However, with the development of the thin package technology, the substrate becomes larger but more thinner. Due to the different coefficient of thermal expansion between the substrate and the molding material, the thermal stress, which is caused by the different extents of the dimensional variations occurring during temperature change in the molding process or the post molding cure process, will induce the warpage of the package structure to affect the following processes. Further, if the warpage of the substrate is severe, the chip adhered thereon will be cracked or the electronic device will be damaged. Therefore, how to overcome the warpage problem of the molding process is a very important issue.

### SUMMARY OF THE INVENTION

One object of the present invention is to provide a substrate package structure which utilizes a plurality of through holes formed at the cutting streets to be penetrated by a molding compound to form a plurality of molding bumps at the edge of the chip carrier so as to improve the edge structure of the chip or the substrate.

To achieve the abovementioned objective, the present invention proposes a substrate package structure which includes a packaging substrate having a plurality of chip carriers set at one surface thereof, wherein the chip carrier are formed by intersecting a plurality of cutting streets. A plurality of through holes are set at the cutting streets and surrounding the chip carriers. And, a plurality of molding areas are formed on another surface of the packaging substrate and opposite to the chip carriers, wherein the molding areas are adjacent to the through holes.

The advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A is a top view illustrating the packaging substrate in accordance with one embodiment of the present invention;

FIG. 1B is an AA cross-sectional schematic diagram of FIG. 1A;

FIG. 1C is a bottom view of FIG. 1A;

FIG. 2 is a top diagram illustrating the packaging substrate according to one embodiment of the present invention; and

FIG. 3 is a top diagram illustrating the packaging substrate according to another embodiment of the present invention.

### DESCRIPTION OF THE PREFERRED EMBODIMENT

The detailed explanation of the present invention is described as following. The described preferred embodiments are presented for purposes of illustration and description, and they are not intended to limit the scope of the present invention.

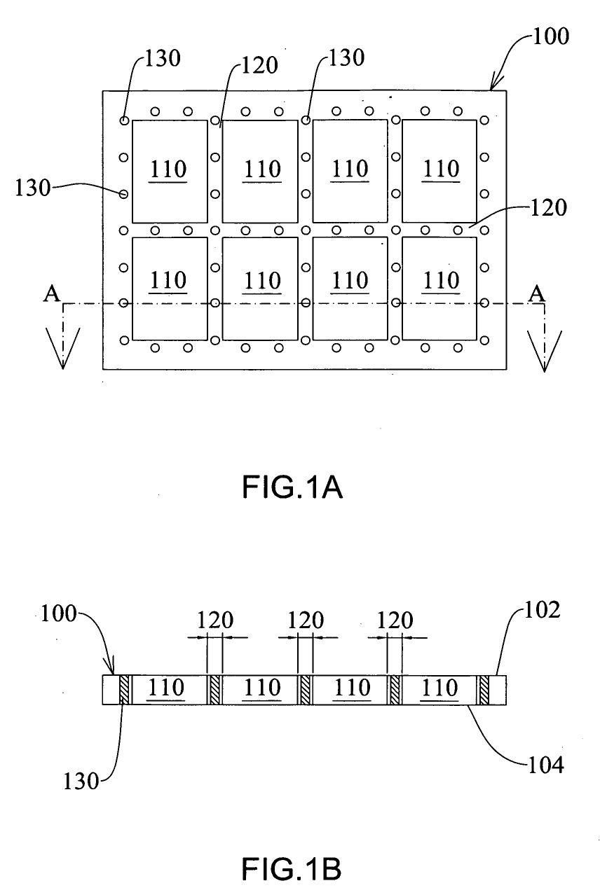

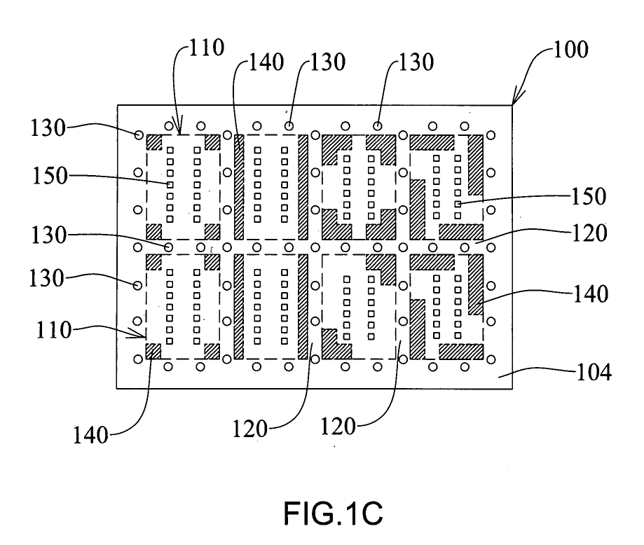

Firstly, refer to FIG. 1A, FIG. 1B, and FIG. 1C. FIG. 1A and FIG. 1B respectively are top views illustrating the packaging substrate and its AA section cross-sectional diagram in accordance with one embodiment of the present invention, and FIG. 1C is a bottom view of FIG. 1A. As shown in these figures, the substrate package structure includes a packaging substrate 100 having a plurality of chip carriers 110 set at one surface thereof, such as the upper surface 102 of the packaging substrate 100. The chip carriers 110 are formed by intersecting a plurality of cutting streets 120. A plurality of through holes 130 set at the cutting streets 130 and surrounding those chip carriers 110. And, a plurality of molding areas 140 formed on another surface of the packaging substrate 100 and opposite to the chip carriers 110, such as the lower surface 104 of the packaging substrate 100. Besides, the molding areas 140 are adjacent to the through holes 130.

Continuing the above description, refer to FIG. 1C, in the embodiment, those through holes 130 are formed within the cutting streets 120, and surround the edge of each chip carriers 110. Then the molding area 140 of the lower surface 104 of the packaging substrate 100 is defined at the edge or the corner of those chip carriers 110. After arranging the chips on the packaging substrate 100 and proceeding the wire bonding method, a molding process is proceeded by utilizing a molding compound (not shown in the figure). In the meantime, the molding compound covers the chips, the wires or other conducting elements, then it flows through those through holes 130 of the upper surface 102 of the packaging substrate 100 to the lower surface 104 of the packaging substrate 100 to cover the molding area 140 of the lower surface 104 of the packaging substrate 100. Due to the coverage of the molding compound, the edge of chips and/or the substrate can be supported and protected. In addition, a plurality of external-connecting pads 150 are set on another surface of the packaging substrate 100 and opposite to each chip carriers 110 so as to electrically connect with an outer device. After that, a singulation process can be progressed to remove the cutting streets to form several semiconductor packages.

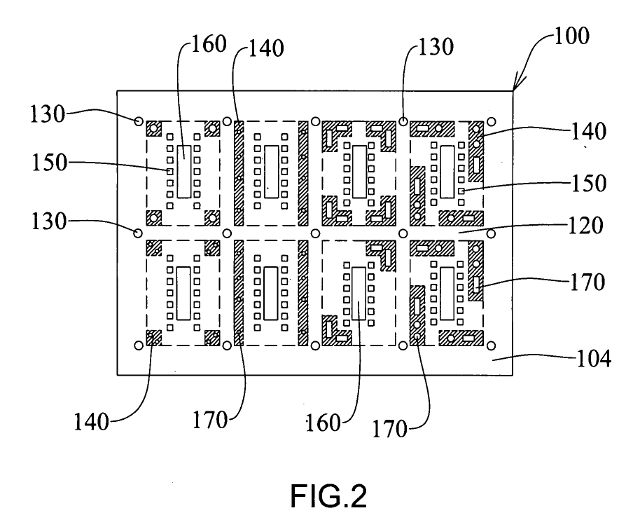

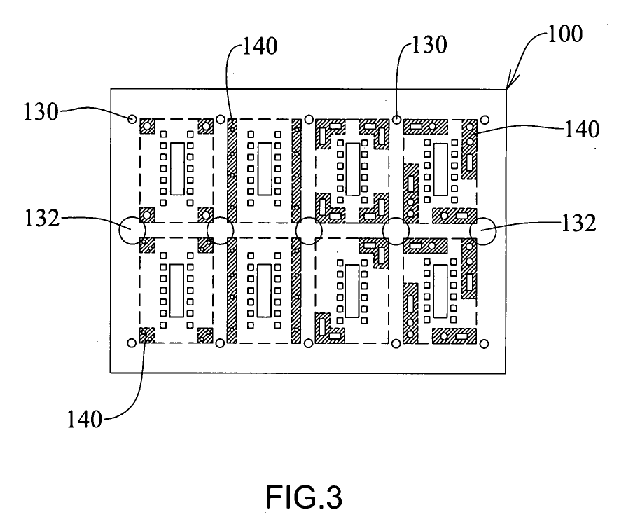

Next, please refer to FIG. 2, in one embodiment, the packaging substrate 100 has a plurality of windows 160 individually formed at the central portion of each chip carriers 110 to meet the demand of the window type semiconductor structures. More, owing to the improvement of the bonding force and the friction between the molding compound and the packaging substrate 100, at least a groove is formed at the molding areas 140 of the packaging substrate 100, such as the grooves 170 is formed at the molding area 140 of the lower surface 104 of the packaging substrate 100, wherein the shape of the groove 170 can have various types; on the other hand, the surface treatment method also can be utilized to roughen a portion surface of the packaging substrate 100 to enhance the friction between the molding compound and the packaging substrate 100. Further, for improving the usage efficiency of the packaging substrate 100, one of those through holes 130 is utilized by at least two molding areas 140. One implementation of the method is to form the through hole 130 at the cross portion of the cutting streets 120 to make the molding areas 140 which are adjacent to the through hole 130 co-use the through hole 130 so as to form a supportable molding bump. Furthermore, in another embodiment, as shown in FIG. 3, those through holes 132 include a portion of the molding areas 140. And those through holes 130, and the through holes 132 can be formed in any position.

According to the above description, one feature of the present invention is to form plural through holes at the cutting streets of the packaging substrate, wherein the shape of those through holes can be varied; and those through holes may be formed at the cross portion of the cutting streets or the edge of those chip carriers. The purpose of those through holes is to pass through the molding compound to form several molding bumps as a support for the structure. Additionally, the adjacent molding areas share the through holes between them. More, those through holes can include a portion of the molding areas to improve the usage efficiency of the packaging substrate. Besides, by forming at least a groove at the lower surface of the packaging substrate or roughening a portion of the surface at the molding area the bonding force between the molding compound and the packaging substrate can be enhanced; the shape and size of the groove are not limited.

To summarize, the present invention is to provide a substrate package structure which utilizes a plurality of through holes formed at the cutting streets and penetrated by a molding compound to form a plurality of molding bumps at the edge of the chip carrier so as to improve the edge crack issue of the chip or the substrate.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A substrate package structure, comprising:
a packaging substrate having a plurality of chip carriers set on one surface thereof, wherein said chip carriers are defined by intersecting a plurality of cutting streets each another;
a plurality of through holes set on said cutting streets and surrounding said chip carriers; and
a plurality of molding areas formed on another surface of said packaging substrate and opposite to said chip carriers, wherein said molding areas are adjacent to said through holes.

2. The substrate package structure according to claim 1, wherein said through holes are formed within said cutting streets.

3. The substrate package structure according to claim 1, wherein at least a groove is formed at said molding areas of said packaging substrate.

4. The substrate package structure according to claim 1, wherein one of said through holes is utilized by at least two said molding areas.

5. The substrate package structure according to claim 1, wherein said molding areas are formed at an edge or a corner of said another surface of said chip carriers.

6. The substrate package structure according to claim 1, wherein said packaging substrate has a plurality of windows individually formed at a central portion of each said chip carrier.

7. The substrate package structure according to claim 1, wherein a plurality of external-connecting pads are set on another surface of said packaging substrate and opposite to each said chip carrier.

8. The substrate package structure according to claim 1, wherein said through holes are formed at a cross portion of said cutting streets.

9. The substrate package structure according to claim 8, wherein a portion of said molding areas comprises a portion of said through holes.
